(19) United States
(12) Patent Application Publication
(10) Pub. No.: US 2026/0210771 A1
(43) Pub. Date: Jul. 23, 2026

(54) MEASUREMENT CIRCUIT AND SEMICONDUCTOR INTEGRATED CIRCUIT

(71) Applicant: Socionext Inc., Kanagawa (JP)

(72) Inventors: Kenta ARUGA, Yokohama (JP); Hiroyuki TOMURA, Yokohama (JP); Hiroshi MORI, Yokohama (JP)

(21) Appl. No.: 19/569,579

(22) Filed: Mar. 17, 2026

Related U.S. Application Data
(63) Continuation of application No. PCT/JP2023/034550, filed on Sep. 22, 2023.

(51) Int. Cl. G01K 7/00; G01R 19/00

(52) U.S. Cl. CPC G01K 7/00; G01R 19/0084

(57) ABSTRACT

A measurement circuit includes a first switch circuit configured to switch a connection between an input side node and an output side node in accordance with a plurality of measurement modes for measuring a plurality of types of physical quantities.

### CROSS-REFERENCE TO RELATED APPLICATIONS

This application is a continuation application of International Application No. PCT/JP2023/034550 filed on Sep. 22, 2023 and designated the U.S., the entire contents of which are hereby incorporated by reference.

### BACKGROUND

The present invention relates to a measurement circuit and a semiconductor integrated circuit.

Conventionally, a thermometer circuit that measures a junction temperature of silicon is sometimes integrated in a semiconductor integrated circuit. For example, a thermometer circuit integrated on a silicon die is used to detect a temperature in a personal computer (PC), a server processor, a mobile system on chip (SoC), or the like (for example, see Patent Documents 1 and 2).

Temperature information indicating a temperature measured by a thermometer circuit is used for controlling a clock frequency, compensating a temperature characteristic of a radio frequency (RF) circuit with high temperature sensitivity, and the like. In a system installed in a vehicle or the like requiring reliability, the temperature information is used, for example, to monitor whether the temperature of a device included in the system is within an allowable range.

In order to improve power efficiency, a dynamic voltage and frequency scaling (DVFS) technology that dynamically controls a power supply voltage in addition to a clock frequency is known. An SoC or the like applying the DVFS technology measures a voltage by a voltmeter circuit integrated on a device, for example, and controls the power supply voltage based on a value of the measured voltage.

A method of integrating a voltmeter circuit on a device using a part of a thermometer circuit integrated on the device is known (for example, see Patent Document 9).

Patent Document 1: Japanese Laid-open Patent Publication No. 2015-190799

Patent Document 2: Japanese National Publication of International Patent Application No. 2018/211554

Patent Document 3: Japanese Laid-open Patent Publication No. 2010-170470

Patent Document 4: Japanese Laid-open Patent Publication No. 2011-186744

Patent Document 5: Japanese Laid-open Patent Publication No. 2014-016860

Patent Document 6: Japanese Laid-open Patent Publication No. 2013-55450

Patent Document 7: Japanese Laid-open Patent Publication No. 2016-111563

Patent Document 8: Japanese Laid-open Patent Publication No. 2019-095271

Patent Document 9: U.S. Patent Application Publication No. 2018/0292271

Patent Document 10: U.S. Patent Application Publication No. 2023/0140251

Patent Document 11: Japanese Laid-open Patent Publication No. 2017-198523

### Non-Patent Documents

Non-Patent Document 1: Akira Yukawa, “Oversampling A-D Conversion Technique,” Nikkei BP, 1990

Non-Patent Document 2: Richard Schreier and Gabor C. Temes, “Introduction to ΔΣ Analog/Digital Converter,” translated by Takao Waho and Akira Yasuda, Maruzen, 2007

### SUMMARY

A measurement circuit includes a first field effect transistor and a first bipolar transistor that are coupled between a first power supply line and a second power supply line via a first node; a second field effect transistor and a second bipolar transistor that are coupled between the first power supply line and the second power supply line via a second node; an analog-to-digital conversion circuit configured to: convert an analog voltage indicating a difference between a voltage at a first differential input node and a voltage at a second differential input node into a digital output value, using a voltage at the first node as a reference voltage, and output the digital output value; and a first switch circuit provided between: an input side node including a voltage measurement node to which a voltage to be measured is supplied, the first node, and the second node, and an output side node including the first differential input node and the second differential input node, the first switch circuit being configured to switch a connection between the input side node and the output side node in accordance with a plurality of measurement modes for measuring a plurality of types of physical quantities.

### BRIEF DESCRIPTION OF THE DRAWINGS

FIG. 1 is a circuit diagram showing an example of a thermometer circuit.

FIG. 2 is a circuit diagram showing an example of a voltmeter circuit.

FIG. 3 is a circuit diagram showing an example of a measurement circuit according to a first embodiment.

FIG. 4 is a timing diagram showing an example of operation of the measurement circuit of FIG. 3.

FIG. 5 is a circuit diagram showing an example of the measurement circuit according to a second embodiment.

FIG. 6 is a circuit diagram showing an example of the measurement circuit according to a third embodiment.

FIG. 7 is a timing diagram showing an example of operation of the measurement circuit of FIG. 6.

FIG. 8 is a circuit diagram showing an example of operation of the measurement circuit according to a fourth embodiment.

FIG. 9 is a timing diagram showing an example of operation of the measurement circuit of FIG. 8.

FIG. 10 is a circuit diagram showing an example of the measurement circuit according to a fifth embodiment.

FIG. 11 is a timing diagram showing an example of operation timing different from that of FIG. 9 in the measurement circuit of FIG. 10.

FIG. 12 is a circuit diagram showing an example of an operational amplifier and switch of FIGS. 8 and 10.

FIG. 13 is a circuit diagram showing an example of a main part of the measurement circuit according to a sixth embodiment.

FIG. 14 is a block diagram showing an example of a semiconductor integrated circuit in which any one of measurement circuits of the embodiments described above is mounted.

### DETAILED DESCRIPTION

Hereinafter, embodiments will be described with reference to the drawings. Hereinafter, codes indicating signals are also each used as a code indicating a signal line, a signal terminal, or a signal node. A code indicating a voltage is also used as a code indicating a voltage line, a voltage terminal, or a voltage node to which a voltage is supplied.

In various semiconductor integrated circuits such as SoCs, one or more sets of thermometer circuits and voltmeter circuits may be integrated. For example, when a plurality of central processing unit (CPU) cores are integrated on a single silicon die functioning as a semiconductor integrated circuit, and each CPU core measures a temperature and a voltage, the number of thermometer circuits and voltmeter circuits increases in proportion to the number of CPU cores.

By using a part of the thermometer circuit and the voltmeter circuit in common, the circuit area becomes smaller than when the thermometer circuit and the voltmeter circuit are provided separately. However, no specific method has been proposed for suppressing the deterioration of accuracy of the measured values of temperature and voltage when using a part of the circuits of the thermometer circuit and the voltmeter circuit in common.

It is an object of the present embodiments to suppress deterioration of accuracy of a measured value of each physical quantity when using a common circuit to measure each of a plurality of types of physical quantities according to a measurement mode.

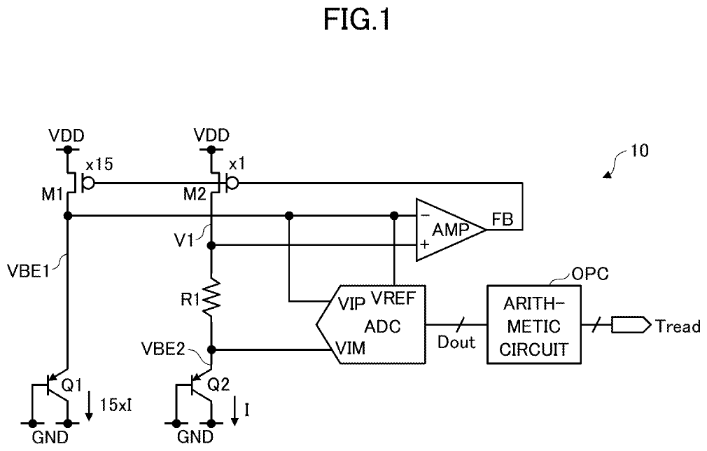

FIG. 1 shows an example of a thermometer circuit. FIG. 1 shows a minimum element for measuring a temperature. A thermometer circuit 10 shown in FIG. 1 includes P-channel metal oxide semiconductor (MOS) transistors M1 and M2, PNP transistors Q1 and Q2, a resistor R1, an operational amplifier AMP, an analog-to-digital converter ADC, and an arithmetic circuit OPC.

Hereinafter, the PNP transistors Q1 and Q2 may be referred to simply as transistors Q1 and Q2, and the P-channel MOS transistors M1 and M2 may be referred to simply as transistors M1 and M2. The analog-to-digital converter ADC may be referred to simply as ADC.

Transistors M1 and Q1 are connected in series between a power supply line VDD and a ground line GND via a node VBE1. A gate of the transistor M1 is connected to an output terminal of an operational amplifier AMP via a feedback node FB. A base of the transistor Q1 is connected to the ground line GND. The node VBE1 that is connected to a drain of the transistor M1 and an emitter of the transistor Q1 is connected to a negative input of the operational amplifier AMP, a positive input terminal VIP of the ADC, and a reference voltage terminal VREF of the ADC.

The transistor M2, the resistor R1, and the transistor Q2 are connected in series between the power supply line VDD and the ground line GND via nodes V1 and VBE2, which are nodes at both ends of the resistor R1. A gate of transistor M2 is connected to the output terminal of the operational amplifier AMP via the feedback node FB. A base of the transistor Q2 is connected to the ground line GND. The node V1 that is connected to a drain of the transistor M2 and one end of the resistor R1 is connected to a positive input of the operational amplifier AMP. The node VBE2 that is connected to the other end of the resistor R1 and an emitter of the transistor Q2 is connected to a negative input terminal VIM of the ADC.

“×15” and “×1” attached to the transistors M1 and M2 indicate that a channel width of the transistor M1 is 15 times a channel width of the transistor M2. “15×I” and “I” attached to the transistors Q1 and Q2 indicate that an emitter current of the transistor Q1 is 15 times an emitter current of the transistor Q2.

The power supply line VDD is an example of a first power supply line, and the ground line GND is an example of a second power supply line. The node VBE1 is an example of a first node, and the node VBE2 is an example of a second node. The node V1 is an example of a third node. The transistor M1 is an example of a first field effect transistor, and the transistor M2 is an example of a second field effect transistor. The transistor Q1 is an example of a first bipolar transistor, and the transistor Q2 is an example of a second bipolar transistor.

The positive input terminal VIP is an example of a first differential input node, and the negative input terminal VIM is an example of a second differential input node. The operational amplifier AMP is an example of a comparison circuit that receives voltages of the nodes VBE1 and V1 at the differential input nodes, compares the voltages, and outputs a voltage representing a comparison result to the gates of the transistors M1 and M2.

In a thermometer circuit 10, the drain current of the transistor M1 is supplied to the emitter of the transistor Q1. The drain current of the transistor M2 is supplied to the emitter of the transistor Q2 via the resistor R1. The operational amplifier AMP operates as a negative feedback circuit, and when the gain of the operational amplifier AMP is sufficiently large, voltages VBE1 and V1 are stabilized at substantially the same potential.

When a base-to-emitter voltage (forward voltage of the PN junction) of a bipolar junction transistor (BJT) is VBE, VBE is expressed by Equation (1).

VBE=Veg−a·T (1)

In Equation (1), Veg represents a bandgap voltage of silicon, T represents the absolute temperature, and a represents the temperature coefficient of the voltage VBE. Here, Veg is known to be about 1.2 V, and the value of a is known to be about 2 mV/° C. Therefore, when T=300 K, VBE is about 600 mV. Equation (1) shows that VBE has a negative temperature coefficient.

The relationship between the emitter current IE of the BJT and the voltage VBE is expressed by Equation (2). In Equation (2), I0 is a constant proportional to an emitter area of the BJT, q is the electron charge, and k is the Boltzmann constant.

IE=I0·exp{q·VBE/(k·T)} (2)

As described above, by negative feedback control of the operational amplifier AMP, the input voltages VBE1 and V1 of the operational amplifier AMP converge to mutually equal potentials. The transistors M1 and M2 have common gates and common sources, and the channel width of the transistor M1 is 15 times the channel width of the transistor M2. Therefore, when the drain current of the transistor M2 is I, the drain current of the transistor M1 is 15×I. As a result, Equations (3) and (4) are obtained from Equation (2).

15×I=I0·exp{q·VBE1/(k·T)} (3)

I=I0·exp{q·VBE2/(k·T)} (4)

When Equation (3) is divided by Equation (4), Equation (5) is obtained. When VBE1−VBE2=ΔVBE, Equation (5) is expressed as Equation (6).

15=exp{q·VBE1/(k·T)−q·VBE2/(k·T)} (5)

ΔVBE=k·T/q·ln15 (6)

From Equation (6), ΔVBE is expressed by the product of a thermal voltage k·T/q and the logarithm of the current ratio of the transistors Q1 and Q2, and has a positive temperature coefficient.

The relationship between the input and output of the ADC is expressed by Equation (7). In Equation (7), Dout indicates a digital output value output from the ADC. The ADC outputs, to an arithmetic circuit OPC, a ratio of the difference between a positive-side input voltage VIP and a negative-side input voltage VIM to a reference voltage VREF, as a digital output value Dout. The arithmetic circuit OPC calculates the temperature of the thermometer circuit 10 based on the digital output value Dout by executing the calculation, and outputs the calculated temperature as a temperature measurement value Tread (calculation result).

Dout=(VIP−VIM)/VREF (7)

Since the positive input terminal VIP and the negative input terminal VIM of the ADC are connected to the nodes VBE1 and VBE2, respectively, and the reference voltage terminal VREF is connected to the node VBE1, Equation (7) is expressed by Equation (8).

Dout=(VBE1−VBE2)/VBE1=ΔVBE/VBE1 (8)

Equation (9) is obtained by applying Equations (1) and (6) to Equation (8).

Dout={k·T/(q·ln15)}/(Veg−a·T) (9)

The numerator of Equation (9) has a positive proportional coefficient to the temperature T, and the denominator of Equation (9) has a negative proportional coefficient to the temperature T. Since the temperature T appears in the numerator and the denominator of Equation (9), it is not suitable to use the measured value of the digital output value Dout as the temperature measured value Tread indicating the temperature. Therefore, as shown in Equation (3) of Patent Document 1, a mathematical model of the thermometer circuit 10 is given by Equation (10). In Equation (10), A, B, and g are constants.

Tread=A+B·ΔVBE/(VBE1+g·ΔVBE) (10)

The denominator of the second term on the right side of Equation (10) is taken out to form Equation (11).

VBE1+g·ΔVBE (11)

As explained in Equation (1), VBE1 has a negative temperature coefficient of −a (about −2 mV/° C.). As shown in Equation (6), ΔVBE has a positive temperature coefficient of k/(q·ln15)≈+233 μV/° C. Therefore, when g is 2 mV/233 μV≈8.6, Equation (11) can be made constant with respect to temperature. When g is set to 8.6, the denominator of the second term on the right side of Equation (10) becomes constant, so that the measured temperature Tread becomes proportional to temperature.

Here, the output voltage value Dout output by the ADC is expressed by Equation (8) above. Then, by dividing the denominator and numerator of the second term of Equation (10) by VBE1, Equation (10) can be transformed into Equation (12).

Tread=A+B·(ΔVBE/VBE1)/{1+g·(ΔVBE/VBE1)}=A+B·Dout/(1+g·Dout) (12)

Based on the model of Equation (12), ΔVBE/VBE1 is the digital output value Dout of the ADC (Equation (8)). In this case, the arithmetic circuit OPC can directly calculate the temperature as the temperature measurement value Tread by applying the digital output value Dout output from the ADC and the constants A, B, and g to Equation (12). The constants A, B, and g can be calculated in advance by measuring the temperature characteristics of the BJT.

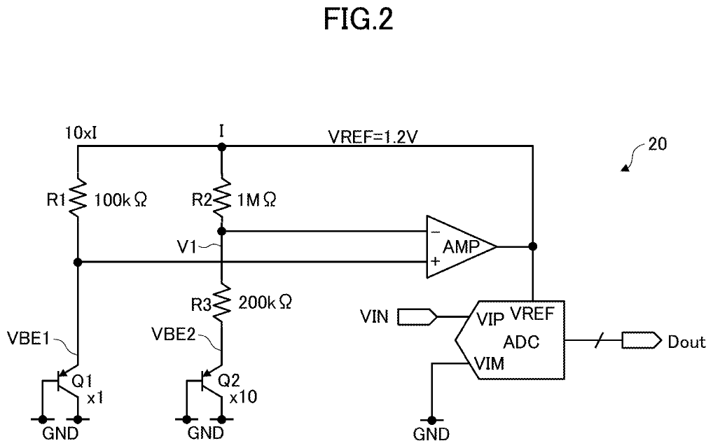

FIG. 2 shows an example of a voltmeter circuit. For example, when a power supply voltage is dynamically controlled in a semiconductor integrated circuit, a voltmeter circuit for measuring the power supply voltage may be integrated in the semiconductor integrated circuit. In FIG. 2, circuit elements similar to those in FIG. 1 are denoted by the same reference numerals as those in FIG. 1. However, in FIGS. 1 and 2, elements having the same reference numerals do not necessarily have the same electrical characteristics.

The voltmeter circuit 20 shown in FIG. 2 includes the PNP transistors Q1 and Q2, resistors R1, R2, and R3, and operational amplifiers AMP and ADC. Although not particularly limited, for example, the resistors R1, R2, and R3 are set to 100 kΩ, 1 MΩ, and 200 kΩ, respectively.

The resistor R1 and the transistor Q1 are connected in series between a reference voltage line VREF and the ground line GND via the node VBE1. The base of the transistor Q1 is connected to the ground line GND. The node VBE1 is connected to the negative input of the operational amplifier AMP. The resistors R2, R3 and the transistor Q2 are connected in series between the reference voltage line VREF and the ground line GND. Resistors R2 and R3 are connected via the node V1, and the resistor R3 and the transistor Q2 are connected via the node VBE2. The base of the transistor Q2 is connected to the ground line GND. The node V1 is connected to the positive input of the operational amplifier AMP.

“I” labeled near the resistor R2 indicates the emitter current of the transistor Q2, and “10×I” labeled near the resistor R1 indicates that the emitter current of transistor Q1 is 10 times the emitter current I of the transistor Q2. “×1” and “×10” added to the transistors Q1 and Q2, respectively, indicate that the emitter area of the transistor Q2 is 10 times the emitter area of the transistor Q1.

In the voltmeter circuit 20 shown in FIG. 2, a circuit other than the ADC operates as a band gap circuit for generating the reference voltage VREF. The band gap circuit has a function of generating a constant reference voltage VREF (for example, 1.2 V) independent of temperature. The band gap circuit is disclosed in Patent Documents 3, 4 and 5.

The reference voltage VREF is supplied to the ADC as a reference voltage of the ADC. The ADC obtains a ratio of the input voltage VIN to the reference voltage and outputs a digital output value Dout indicating the input voltage VIN. Since the reference voltage VREF is constant with respect to temperature, the ADC can output the input voltage VIN that is received at the positive-side input terminal VIP as a digital output value Dout having no temperature dependence.

In FIG. 2, when the voltage gain of the operational amplifier AMP is sufficiently large, the input voltages VBE1 and V1 of the operational amplifier AMP become substantially equal, and the circuit becomes stable. As a result, when the resistance values of the resistors R1 and R2 are designed to be, for example, 1:10 (100 kΩ and 1 MΩ) , currents flowing through the transistors Q1 and Q2 have a ratio of 10:1.

For example, when the emitter area of the transistor Q2 is 10 times the emitter area of the transistor Q1, and base-emitter voltages of the transistors Q1 and Q2 are represented by VBE1 and VBE2, respectively, Equations (13) and (14) are obtained from Equation (2).

10×I=I0·exp{q·VBE1/(k·T)} (13)

I=10×I0·exp{q·VBE2/(k·T)} (14)

Equation (15) is obtained by dividing Equation (13) by Equation (14), and Equation (16) is obtained by representing VBE1−VBE2 in Equation (15) by ΔVBE.

100=exp{q·k·T·(VBE1−VBE2)} (15)

ΔVBE=k·T/q·ln100 (16)

That is, the difference ΔVBE between the base-emitter voltages of the transistors Q1 and Q2 is represented by the product of the logarithm (ln100) of the current density ratio 100 of the transistors Q1 and Q2 and the thermal voltage k·T/q. Since the voltages V1 and VBE1 are equal to each other and ΔVBE is equal to the potential difference across the resistor R3, a current represented by ΔVBE/R3 flows through the resistors R2 and R3. Therefore, if the potential difference across the resistor R2 is VR2, the current flowing through the resistor R2, which is denoted by VR2/R2, is equal to ΔVBE/R3, so that Equation (17) is obtained.

VR2=ΔVBE·(R2/R3) (17)

VR2 is expressed as “VREF−V1,” and the voltages VBE1 and V1 are equal to each other. Therefore, the potential of the reference voltage VREF, which is expressed by V1+VR2=VBE1+VR2, is expressed by the equation (18) using the equation (17).

VREF=VBE1+ΔVBE·(R2/R3) (18)

VBE1 in the first term on the right side of Equation (18) is the forward voltage of the PN junction, and has a negative temperature dependence that decreases with increasing temperature, as shown in Equation (1). On the other hand, ΔVBE in the second term on the right side of Equation (18) increases in proportion to temperature, as shown in Equation (16). Therefore, the voltmeter circuit 20 that generates the voltage VREF, which is independent of temperature, can be designed by appropriately selecting a resistance value R2 and a ratio R2/R3 of R2. The value of the voltage VREF at this time is 1.2 V corresponding to the bandgap voltage of silicon.

Although, in the thermometer circuit 10 of FIG. 1 and the voltmeter circuit 20 of FIG. 2, ADCs are shown as blocks, for the purpose of measuring DC voltages such as the measurement of a temperature or a power supply voltage, for example, a delta-sigma ADC is suitable. The delta-sigma ADC is disclosed in Patent Document 6, Non-Patent Document 1, and Non-Patent Document 2.

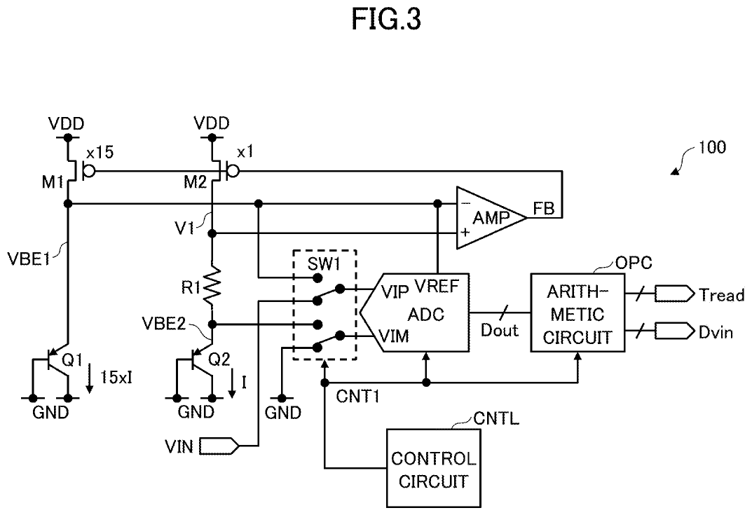

FIG. 3 shows an example of a measurement circuit according to the first embodiment. In the measurement circuit 100 shown in FIG. 3, a switch circuit SW1 and a control circuit CNTL are added to the thermometer circuit 10 of FIG. 1, and the function of the thermometer circuit 10 of FIG. 1 and the function of the voltmeter circuit 20 of FIG. 2 are combined. The control circuit CNTL is an example of a switch control circuit. The control circuit CNTL may be disposed outside the measurement circuit 100. For example, the measurement circuit 100 is mounted on a semiconductor integrated circuit and measures the temperature of the semiconductor integrated circuit and the voltage (for example, supply voltage) used in the semiconductor integrated circuit. The temperature and the voltage are examples of physical quantities. The measurement circuit 100 may be used to control the DVFS of a semiconductor integrated circuit.

The switch circuit SW1 is connected to the nodes VBE1 and VBE2, the input voltage line VIN and the ground line GND, and the positive input terminal VIP and the negative input terminal VIM of the ADC. When the control signal CNT1 from the control circuit CNTL indicates a temperature measurement mode, the switch circuit SW1 connects the positive input terminal VIP to the node VBE1 and connects the negative input terminal VIM to the node VBE2.

In this case, the measurement circuit 100 has the same circuit configuration as the thermometer circuit 10 in FIG. 1, and outputs a temperature measurement value Tread indicating the temperature of the measurement circuit 100 from the arithmetic circuit OPC as a measurement result. That is, the arithmetic circuit OPC can suppress accuracy deterioration of the temperature measurement value Tread measured in the temperature measurement mode by applying the value of g set based on the above Equation (11) to Equation (10). The temperature measurement mode is an example of a first measurement mode.

When the control signal CNT1 from the control circuit CNTL indicates the voltage measurement mode, the switch circuit SW1 connects the positive-side input terminal VIP to the input voltage line VIN and connects the negative-side input terminal VIM to the ground line GND. In this case, the measurement circuit 100 operates as a voltmeter circuit and outputs a voltage measurement value Dvin indicating the input voltage VIN from the arithmetic circuit OPC as a measurement result. The ground line GND is an example of a fixed voltage node, and the ground voltage GND supplied to the ground line GND is an example of a fixed voltage.

The switch circuit SW1 is an example of the first switch circuit. In the switch circuit SW1, nodes connected to the nodes VBE1, VBE2, the input voltage line VIN, and the ground line GND are examples of input side nodes, and nodes connected to the positive-side input terminal VIP and the negative-side input terminal VIM are examples of output side nodes. The input voltage line VIN is an example of a voltage measurement node to which a voltage to be measured is supplied.

In the switch circuit SW1, when the control signal CNT1 indicates the voltage measurement mode, the positive-side input terminal VIP is connected to the input voltage line VIN, and the negative-side input terminal VIM is connected to the ground line GND. The voltage measurement mode is an example of a second measurement mode. Here, the ground voltage GND is supplied to the negative-side input terminal VIM of the ADC, and the voltage VBE1 is supplied to the reference voltage terminal VREF of the ADC. Therefore, the digital output value Dout output by the ADC is VIP/VBE1, which is expressed by Equation (19) using Equation (1).

Dout=VIP/(Veg−a·T) (19)

Since the denominator on the right side of Equation (19) has a negative temperature coefficient, the digital output value Dout does not correspond to the input voltage VIN. For example, even when the input voltage VIN does not change, the digital output value Dout increases as the temperature increases.

In this embodiment, the measurement circuit 100 measures the temperature in the temperature measurement mode and then measures the voltage in the voltage measurement mode. Therefore, the arithmetic circuit OPC corrects the temperature of the digital output value Dout of the input voltage VIN that is converted by the ADC by using the temperature measurement value Tread acquired in the temperature measurement mode.

For example, the arithmetic circuit OPC cancels the temperature coefficient of the denominator by multiplying the digital output value Dout indicating the input voltage VIN by “Veg−a·Tread.” If the digital value corresponding to the input voltage VIN is the input voltage value Dvin and the temperature measurement value Tread is T, the input voltage value Dvin is expressed by Equation (20), and the input voltage value Dvin indicating the input voltage VIN supplied to the positive input voltage VIP of the ADC can be obtained. However, the temperature measurement value Tread is assumed to be sufficiently accurate. The first term on the right side of Equation (20) is the digital output value Dout as shown in Equation (19).

Dvin=VIP/(Veg−a·T)×(Veg−a·Tread)=VIP/(Veg−a·T)×(Veg−a·T)=VIP (20)

Here, the constant a used in “Veg−a·Tread” is approximately 2 mV/° C., as explained in Equation (1). More precisely, it is reasonable to make it consistent with the constant used in measuring the temperature. In the temperature measurement explained in FIG. 1, the constant g is set so that Equation (11) is constant with the temperature and used for calculating the temperature. Equation (21) is derived by substituting the right side of Equation (1) into the first term of Equation (11) and the right side of Equation (6) into the second term of Equation (11).

Veg−a·T+g·k·T/(q·ln15)=constant (21)

Since Equation (21) is constant, a can be expressed as “g·k/(q·ln15).” Here, g is the value for the temperature measurement described in FIG. 1. k is the Boltzmann constant, q is a constant indicating the charge of an electron, and ln15 is a constant.

As a result, by substituting the temperature measurement value Tread that is obtained in the temperature measurement mode, the digital output value Dout, and the constants a and Veg into the first line of Equation (20), the arithmetic circuit OPC can calculate the voltage measurement value Dvin that corresponds to the input voltage VIN and is independent of the temperature. As a result, accuracy deterioration of the voltage measurement value Dvin measured in the voltage measurement mode can be suppressed. The digital output value Dout represents the input voltage VIN that is received at the positive-side input terminal VIP during the voltage measurement mode and is represented by “VIP/(Veg−a·T).”

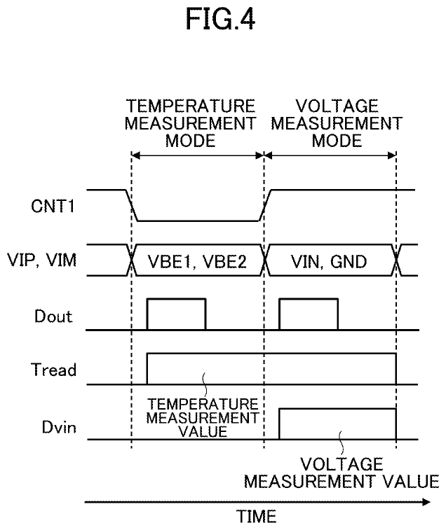

FIG. 4 shows an example of operation timing of the measurement circuit 100 of FIG. 3. The operation shown in FIG. 4 is realized by operating each circuit in the measurement circuit 100, such as the ADC and the arithmetic circuit OPC, based on control by the control circuit CNTL. The measurement circuit 100 measures the temperature and voltage in this order.

The control circuit CNTL first outputs a low-level control signal CNT1 to the switch circuit SW1, and switches the switch circuit SW1 to a temperature measurement mode. In the temperature measurement mode, the switch circuit SW1 connects the positive-side input terminal VIP to the node VBE1, and connects the negative-side input terminal VIM to the node VBE2.

The ADC operates in response to the falling edge of the control signal CNT1 and outputs a digital output value Dout corresponding to the input voltages VIP and VIM. When receiving the low-level control signal CNT1, the arithmetic circuit OPC calculates a temperature measurement value Tread from the digital output value Dout output from the ADC and outputs the calculated temperature measurement value Tread.

Next, the control circuit CNTL outputs the high-level control signal CNT1 to the switch circuit SW1 and switches the switch circuit SW1 to the voltage measurement mode. In the voltage measurement mode, the switch circuit SW1 connects the positive-side input terminal VIP to the input voltage line VIN and connects the negative-side input terminal VIM to the ground line GND.

The ADC operates in response to the rising edge of the control signal CNT1 and outputs the digital output value Dout corresponding to the input voltages VIP and VIM. When receiving the high-level control signal CNT1, the arithmetic circuit OPC calculates the voltage measurement value Dvin based on the digital output value Dout output from the ADC and outputs the calculated voltage measurement value Dvin.

In the measurement circuit 100 shown in FIG. 3, an analog operation performed by the bandgap circuit in FIG. 2 can be replaced by the digital operation. That is, in the measurement circuit 100, the main operation is numerically performed by using the digital value after the AD conversion, so that the characteristic is not appreciably affected by manufacturing error of the measurement circuit 100 and the temperature change, and an accurate measurement result can be obtained.

On the other hand, in the voltmeter circuit 20 shown in FIG. 2, a bandgap circuit for generating a constant reference voltage VREF with respect to the temperature is provided, and the ADC generates a digital output value Dout by using the reference voltage VREF. The bandgap circuit is an analog operation circuit for adding R2/R3 times the voltage difference ΔVBE, which has a positive temperature coefficient, to the voltage VBE1, which has a negative temperature coefficient, as shown in Equation (18). Each element used in the analog operation has variations due to manufacturing error, and the characteristic also changes when the temperature changes. Therefore, the operation shown in Equation (18) is uncertain in that the result varies depending on the individual differences (manufacturing variations) of the voltmeter circuit 20 and the temperature.

As described above, in the first embodiment, the operation circuit OPC executes different operations in the temperature measurement mode and the voltage measurement mode, and calculates the temperature measurement value Tread and the voltage measurement value Dvin, respectively. In this way, even when the electrical characteristics of the elements included in the measurement circuit 100 vary due to the manufacturing variations or the like, it is possible to suppress accuracy deterioration of the temperature measurement value Tread and the voltage measurement value Dvin measured using the common measurement circuit 100.

Since the functions of the thermometer circuit 10 of FIG. 1 and the voltmeter circuit 20 of FIG. 2 can be realized by one measurement circuit 100, the circuit area of the measurement circuit 100 for measuring temperature and voltage can be made smaller than the sum of the circuit areas of the two circuits for measuring temperature and voltage, respectively. When a plurality of measurement circuits 100 are mounted on a semiconductor integrated circuit, the effect of reducing the area can be increased as the number of mounted measurement circuits 100 increases.

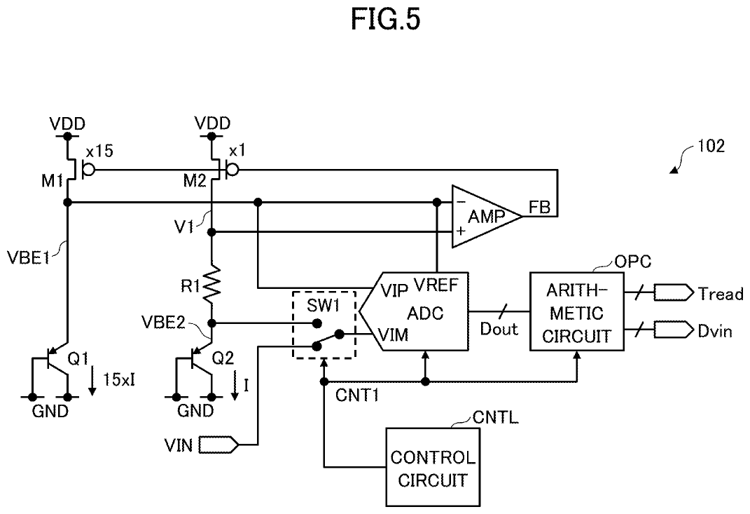

FIG. 5 shows an example of a measurement circuit according to the second embodiment. The same or similar elements as those in FIG. 3 are denoted by the same reference numerals, and detailed description thereof is omitted. FIG. 5 has the same circuit configuration as that in FIG. 3, except that the configuration and function of the switch circuit SW1 for selecting the voltage to be supplied to the ADC are different from those of the switch circuit SW1 in FIG. 3.

In the measurement circuit 102 shown in FIG. 5, the positive-side input terminal VIP of the ADC is connected to the node VBE1. The switch circuit SW1 connects the node VBE2 or the input voltage line VIN to the negative-side input terminal VIM of the ADC. When the control signal CNT1 from the control circuit CNTL indicates the temperature measurement mode, the switch circuit SW1 connects the negative input terminal VIM to the node VBE2. In this case, the measurement circuit 102 has the same circuit configuration as the thermometer circuit 10 in FIG. 1, and the measurement circuit 102 can obtain the temperature measurement value Tread.

When the control signal CNT1 indicates the voltage measurement mode, the switch circuit SW1 connects the negative input terminal VIM to the input voltage line VIN. The digital output value Dout output from the ADC in the voltage measurement mode is expressed by Equation (22) by substituting Equation (1) into Equation (7).

Dout=(Veg−a·T−VIN)/(Veg−a·T) (22)

Assume that the temperature measurement value Tread calculated in the temperature measurement mode is sufficiently accurate and Tread=T. In this case, multiplying both sides by the denominator on the right side of Equation (22), and replacing the input voltage VIN with a voltage measurement value Dvin, Equation (23) expresses the voltage measurement value Dvin.

Dvin=(Dout−1)×(Veg−a·Tread)={(Veg−a·T−VIN)/(Veg−a·T)−1}×(Veg−a·Tread)={1−VIN/(Veg−a·T)−1}×(Veg−a·Tread) =−VIN (23)

As described above, the input voltage value Dvin having no temperature dependence is obtained in accordance with the voltage value VIN. The arithmetic circuit OPC can calculate the input voltage value Dvin corresponding to the input voltage VIN and having no temperature dependence by substituting the digital output value Dout, the temperature measurement value Tread obtained in the temperature measurement mode, and the constants Veg and a into the first line of Equation (23). Since the signs of the input voltage VIN and the voltage measurement value Dvin are opposite in Equation (23), the arithmetic circuit OPC inverts the sign of the voltage measurement value Dvin calculated using Equation (23) and outputs it. The operation timing of the measurement circuit 102 shown in FIG. 5 is the same as that of FIG. 4.

As described above, the same effect as that of the first embodiment can be obtained in the second embodiment. For example, the arithmetic circuit OPC executes different arithmetic operations in the temperature measurement mode and the voltage measurement mode to calculate the temperature measurement value Tread and the voltage measurement value Dvin, respectively. In this way, even if the electrical characteristics of the elements included in the measurement circuit 102 vary due to manufacturing variations or the like, it is possible to suppress deterioration in the accuracy of the temperature measurement value Tread and the voltage measurement value Dvin measured by using the common measurement circuit 102.

Further, since the functions of the thermometer circuit 10 of FIG. 1 and the voltmeter circuit 20 of FIG. 2 can be realized by one measurement circuit 102, the circuit area of the measurement circuit 102 for measuring temperature and voltage can be made smaller than the sum of the circuit areas of the thermometer circuit 10 and the voltmeter circuit 20. Furthermore, in the second embodiment, the circuit scale of the switch circuit SW1 can be made smaller than the circuit scale of the switch circuit SW1 of the measurement circuit 100 of FIG. 3, thereby making it possible to further reduce the circuit area.

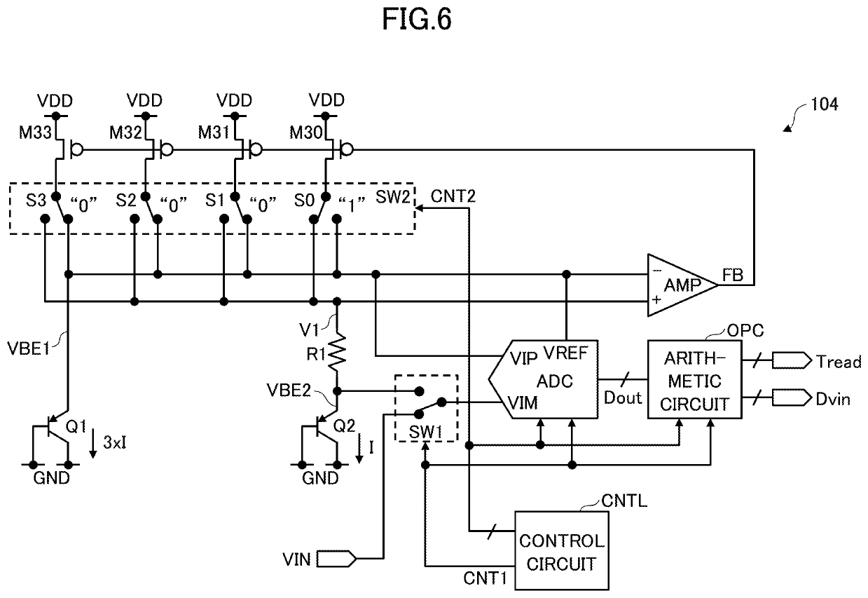

FIG. 6 shows an example of the measurement circuit according to a third embodiment. The same or similar elements as those in FIG. 5 are denoted by the same reference numerals, and detailed description thereof is omitted. The measurement circuit 104 shown in FIG. 6 has transistors M30, M31, M32, and M33 arranged in place of the transistors M1 and M2 of FIG. 5, and has a switch circuit SW2 for switching the connection between the transistors M30 to M33 and the nodes VBE1 and V1. The transistors M30 to M33 are examples of the third field-effect transistor. The switch circuit SW2 is an example of the second switch circuit.

The output node of the preamplifier AMP is connected to the gates of the transistors M30 to M33 via the feedback node FB. The control circuit CNTL outputs a control signal CNT2 for controlling the switch circuit SW2 in addition to the control signal CNT1 for controlling the switch circuit SW1. The control signal CNT2 is also supplied to the ADC and the arithmetic circuit OPC. The other configuration of the measurement circuit 104 is the same as that of the measurement circuit 102 shown in FIG. 5. Hereinafter, when the transistors M30, M31, M32, and M33 are described without distinction, they are also referred to as transistors M3.

In the measurement circuit 100 shown in FIG. 3 and the measurement circuit 102 shown in FIG. 5, the channel widths of the transistors M1 and M2 are set to a ratio of 15:1 in order to determine the current ratio of the transistors Q1 and Q2, and the ratio of 15:1 is expected to be accurate when calculating the temperature.

Therefore, for example, if the current ratio of the transistors Q1 and Q2 changes from the ratio of 15:1 due to manufacturing variations in the transistors M1 and M2, an error occurs in the temperature measurement value Tread. If the ratio of 15:1 changes, an error also occurs in the voltage measurement value Dvin, which is calculated with the expectation that the temperature measurement value Tread is accurate.

On the other hand, in the measurement circuit 104 shown in FIG. 6, three of the plurality of transistors M3 having the same size are connected to the transistor Q1 by the switch circuit SW2, and the remaining one transistor M3 is connected to the transistor Q2. That is, the switch circuit SW2 switches a combination of the transistors M3 connected to the transistors Q1 and Q2.

In the measurement circuit 104 shown in FIG. 6, in order to obtain the same current ratio of 15:1 between the transistors Q1 and Q2 in the measurement circuits 100 and 102 shown in FIGS. 3 and 5, it is desirable to arrange 16 transistors M3, connect 15 of the 16 transistors M3 to the transistor Q1, and connect the remaining 1 transistor M3 to the transistor Q2. However, in FIG. 6, for simplicity of explanation, 4 transistors M3 are arranged, and the current ratio of the transistors Q1 and Q2 is set to 3:1.

The switch circuit SW2 has switches S0 to S3 connected to the transistors M30 to M33. For example, the control circuit CNTL outputs a 4-bit control signal CNT2 for controlling the switches S0 to S3 to the switch circuit SW2. One bit of the 4-bit control signal CNT2 is set to “1,” and the remaining three bits are set to “0.”

“0” in the switch circuit SW2 indicates that the transistor M3 is connected to the transistor Q1. “1” in the switch circuit SW2 indicates that the transistor M3 is connected to the transistor Q2. Thus, the current ratio of the emitter currents of the transistors Q1 and Q2 can always be maintained at 3:1 while switching the transistors M3 connected to the transistors Q1 and Q2.

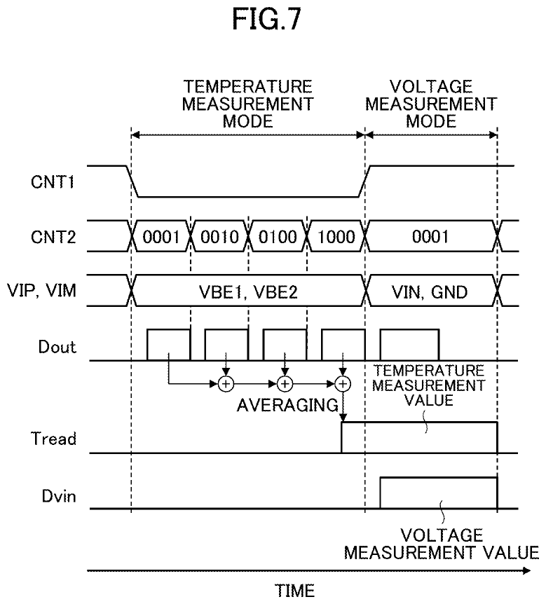

FIG. 7 shows an example of the operation timing of the measurement circuit of FIG. 6. The same or similar operation as that of FIG. 4 will not be described in detail. The operation in the voltage measurement mode is the same as that of FIG. 4. The control circuit CNTL of FIG. 6 sequentially changes the logic level of the control signal CNT2 during the temperature measurement mode in which the control signal CNT1 is set to a low level. Among the four transistors M3, the control circuit CNTL sequentially switches over three transistors M3 connected to the transistor Q1 and sequentially switches over one transistor M3 connected to the transistor Q2.

The 4 bits shown in the control signal CNT2 of FIG. 7 correspond to the transistors M30, M31, M32, and M33 from the right side. The transistor M3 corresponding to the bit value “0” is connected to the transistor Q1, and the transistor M3 corresponding to the bit value “1” is connected to the transistor Q2. In FIG. 7, “0001” of the control signal CNT2 that is output first indicates the state of the switch circuit SW2 of FIG. 6.

Due to a slight difference in the electrical characteristics of the transistor M3 connected to the transistors Q1 and Q2, voltages VBE1 and VBE2 generated in the nodes VBE1 and VBE2 vary. The ADC generates a digital output value Dout every time the logic level of the control signal CNT2 is switched.

The ADC operates synchronously with the transition edge of the control signal CNT2, and outputs a digital output value Dout corresponding to the input voltages VIP and VIM. The arithmetic circuit OPC acquires the digital output value Dout after a predetermined delay time from the transition edge of the control signal CNT2, and integrates the acquired digital output values Dout. Then, the arithmetic circuit OPC calculates an average value of the integrated 4 digital output values Dout, and outputs the calculated average value as a temperature measurement value Tread. Since the arithmetic circuit OPC only needs to calculate an average value of the digital output values Dout, this can be realized by numerical calculation.

For example, it is assumed that the drain current of the transistor M30 corresponds to ×1.1 and the drain current of the transistors M31 to M33 corresponds to ×1 due to manufacturing variations of the transistors M30 to M33. In this case, the current ratio of the transistors Q1 and Q2 is 1.1:3 for the first control signal CNT2 (=0001), and 1:3.1 for each of the second to fourth control signals CNT2 (=0010, 0100, 1000).

When the four ratios are respectively added on the left side and the right side, the ratio becomes (1.1+1+1+1):(3+3.1+3.1+3.1)=1:3. Therefore, the influence of variations in the electrical characteristics of the transistors M30 to M33 can be eliminated by averaging the digital output values Dout measured 4 times by switching the switches S0 to S3.

As a result, the error of the temperature measurement value Tread caused by the manufacturing variation of the transistors M30 to M33 can be canceled. Furthermore, in the subsequent voltage measurement mode, the influence of the manufacturing variation of the transistors M30 to M33 on the voltage measurement value Dvin calculated using the temperature measurement value Tread can be suppressed.

It is known that the variation in the electrical characteristics of MOS transistors is relatively large as the area of the channel is small. Therefore, in the measurement circuits 100 and 102 shown in FIGS. 3 and 5 for calculating the temperature measurement value Tread from one digital output value Dout, the total area of the channels of the transistors M1 and M2 for determining the current ratio of the transistors Q1 and Q2 must be sufficiently larger than the total area of the channel of the transistor M3. In other words, in the measurement circuit 104 shown in FIG. 5, the total area of the transistor M3 can be made smaller than the total area of the transistors M1 and M2 shown in FIGS. 3 and 5.

Note that the switch circuit SW1 of the measurement circuit 104 shown in FIG. 6 may be replaced with the switch circuit SW1 shown in FIG. 3. In this case, the operation is the same as that of FIG. 7, and it is possible to suppress the influence of variations in the electrical characteristics of the transistor M3 on the temperature measurement value Tread and the voltage measurement value Dvin.

In the measurement circuit 104 shown in FIG. 6, the current ratio of the transistors Q1 and Q2 is 3:1, but the current ratio can be arbitrarily set. The greater the current ratio, the greater the voltage of ΔVBE (=VBE1−VBE2). Therefore, it is desirable to increase the current ratio in order to improve measurement accuracy.

On the other hand, if the current ratio is increased, the number of transistors M3 mounted in the measurement circuit 104 and the number of switches included in the switch circuit SW2 increase, so that the circuit size increases. In addition, since the number of combinations connected to the transistors Q1 and Q2 increases, the measurement time increases. Therefore, the number of transistors M3 is determined in consideration of a balance among the requirements for measurement accuracy, circuit size, and measurement time. For example, if the total area of the transistors M30 to M33 and the switch circuit SW2 can be made smaller than the total area of the transistors M1 and M2 in FIG. 5, the size of the measurement circuit 104 can be made smaller than the size of the measurement circuit 102 in FIG. 5.

As described above, in the third embodiment, the same effect as in the first and second embodiments can be obtained. Furthermore, in the third embodiment, by sequentially switching the plurality of transistors M3 connected to the transistors Q1 and Q2 in the temperature measurement mode, error in the temperature measurement value Tread caused by manufacturing variation of the transistors M3 can be canceled. Furthermore, in the subsequent voltage measurement mode, the influence of manufacturing variation of the transistors M3 on the voltage measurement value Dvin calculated using the temperature measurement value Tread can be suppressed. As a result, the deterioration of the accuracy of the temperature measurement value Tread and the voltage measurement value Dvin measured using the common measurement circuit 104 can be further suppressed.

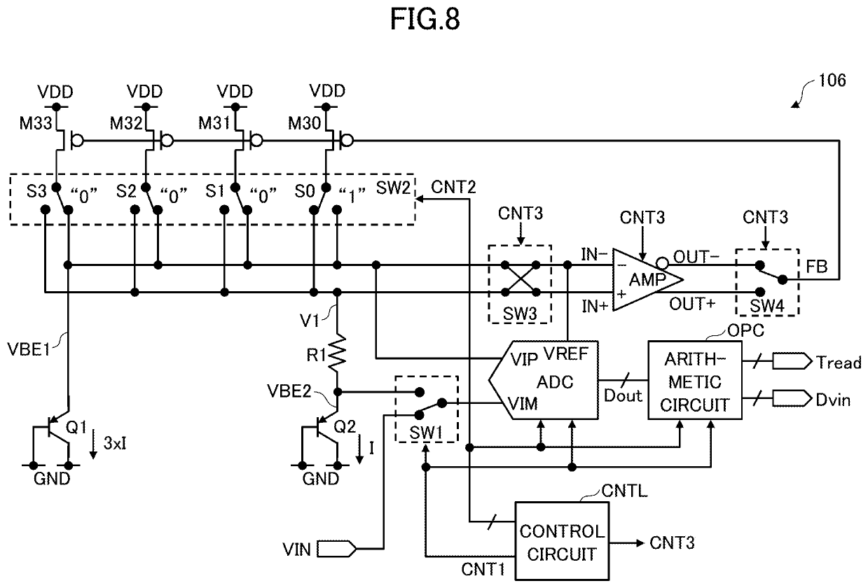

FIG. 8 shows an example of the measurement circuit in the fourth embodiment. The same or similar elements as those in FIG. 6 are denoted by the same reference numerals, and a detailed description thereof is omitted. The measurement circuit 106 shown in FIG. 8 has the same configuration as the measurement circuit 104 shown in FIG. 6, except that the operational amplifier AMP has a differential output and switch circuits SW3 and SW4 controlled by the control signal CNT3 are connected to the input and output of the operational amplifier AMP, respectively. The control signal CNT3 is generated by the control circuit CNTL. The switch circuit SW3 is an example of a third switch circuit, and the switch circuit SW4 is an example of a fourth switch circuit.

In the measurement circuit 106 shown in FIG. 8, the polarity of the differential input and the polarity of the differential output of the operational amplifier AMP are exchanged by the control signal CNT3, thereby canceling the offset voltage of the operational amplifier AMP. The operational amplifier AMP is an example of a comparison circuit that receives and compares the voltages of the nodes VBE1 and V1 at the differential input nodes IN− and IN+, and outputs the voltages indicating the comparison results to the differential output nodes OUT− and OUT+.

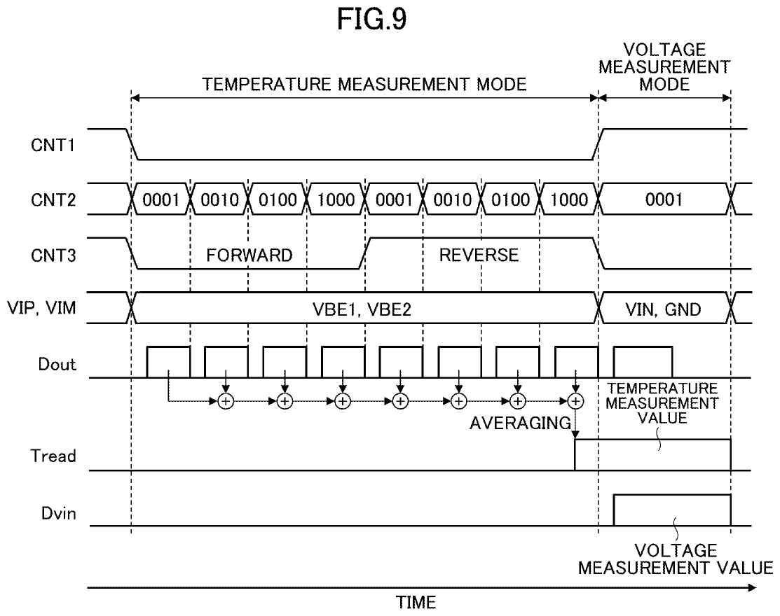

FIG. 9 shows an example of the operation timing of the measurement circuit 106 shown in FIG. 8. A detailed description of the same or similar operation as in FIG. 7 is omitted. The operation in the voltage measurement mode is the same as in FIG. 7. During the temperature measurement mode in which the control signal CNT1 is set to the low level, the control circuit CNTL shown in FIG. 8 sequentially sets the logical level of the control signal CNT3 to the low level and the high level.

During the low level period of the control signal CNT3, the switch circuit SW3 connects the node VBE1 to the negative input (IN−) of the operational amplifier AMP and connects the node V1 to the positive input (IN+) of the operational amplifier AMP. During the low level period of the control signal CNT3, the switch circuit SW4 connects the output OUT− of the operational amplifier AMP to the feedback node FB.

During a high level period of the control signal CNT3, the switch circuit SW3 connects the node VBE1 to the positive input of the operational amplifier AMP and connects the node V1 to the negative input of the operational amplifier AMP. During the high level period of the control signal CNT3, the switch circuit SW4 connects the output OUT+ of the operational amplifier AMP to the feedback node FB.

“Forward” indicated by the control signal CNT3 indicates that the node VBE1 is connected to the negative input (IN−) of the operational amplifier AMP, the node V1 is connected to the positive input (IN+) of the operational amplifier AMP, and the output OUT− of the operational amplifier AMP is connected to the feedback node FB. “Reverse” indicated by the control signal CNT3 indicates that the node VBE1 is connected to the positive input (IN+) of the operational amplifier AMP, the node V1 is connected to the negative input (IN−) of the operational amplifier AMP, and the output OUT− of the operational amplifier AMP is connected to the feedback node FB.

The negative input (IN−) of the operational amplifier AMP is an example of a third differential input node, and the positive input (IN+) of the operational amplifier AMP is an example of a fourth differential input node. The output OUT− of the operational amplifier AMP is an example of a first differential output node, and the output OUT+ of the operational amplifier AMP is an example of a second differential output node.

In addition, the control circuit CNTL sequentially changes a logic level of the control signal CNT2 in each of the low level period and the high level period of the control signal CNT3 as shown in FIG. 8. Among the four transistors M3, the control circuit CNTL sequentially switches over three transistors M3 connected to the transistor Q1 and sequentially switches over one transistor M3 connected to the transistor Q2.

In the temperature measurement mode, the ADC outputs the digital output value Dout to the arithmetic circuit OPC four times each during a “forward” period and a “reverse” period of the control signal CNT3. The arithmetic circuit OPC integrates the digital output value Dout received eight times from the ADC, calculates an average value of the integrated eight digital output values Dout, and outputs the calculated average value as the temperature measurement value Tread.

In the voltage measurement mode, the arithmetic circuit OPC calculates the temperature measurement value Tread using the averaged digital output value Dout. As a result, the measurement circuit 106 can calculate the temperature measurement value Tread in which the manufacturing variation of the transistors M30 to M33 and the offset voltage of the operational amplifier AMP are canceled. Furthermore, in the subsequent voltage measurement mode, the voltage measurement value Dvin in which the manufacturing variation of the transistors M30 to M33 and the offset voltage of the operational amplifier AMP are canceled can be calculated using the temperature measurement value Tread.

As described above, in the fourth embodiment, the same effects as those of the first to third embodiments can be obtained. Furthermore, in the fourth embodiment, the temperature measurement value Tread and the voltage measurement value Dvin in which the manufacturing variations of the transistors M30 to M33 and the offset voltage of the operational amplifier AMP are canceled can be calculated. As a result, a decrease in accuracy of the temperature measurement value Tread and the voltage measurement value Dvin measured by using the common measurement circuit 106 can be further suppressed. Note that the switch circuits SW3 and SW4 may be disposed at the input and the output of the operational amplifier AMP shown in FIGS. 3 and 5, respectively.

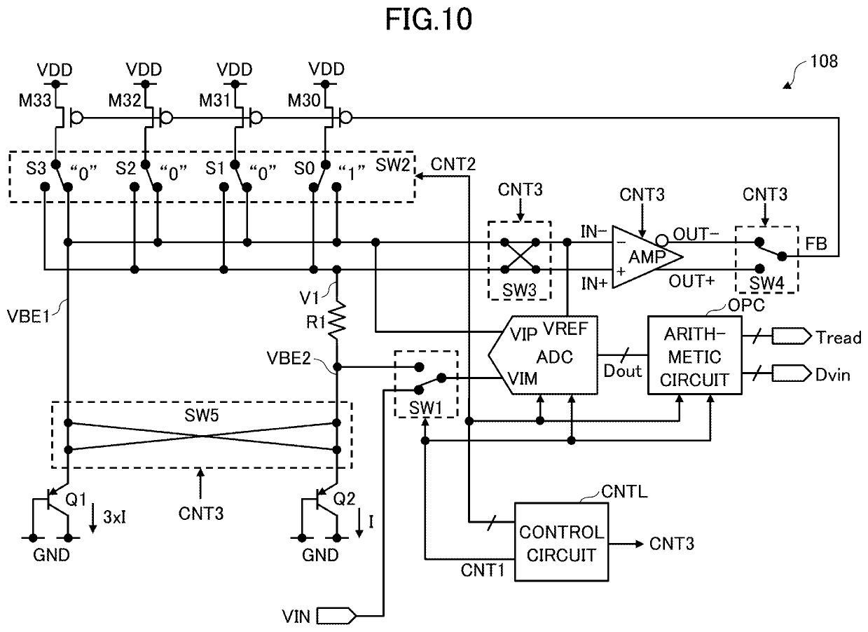

FIG. 10 shows an example of the measurement circuit according to a fifthe embodiment. The same or similar elements as those in FIG. 8 are denoted by the same reference numerals, and detailed description thereof is omitted. The measurement circuit 108 shown in FIG. 10 has the same configuration as the measurement circuit 106 shown in FIG. 8, except that the switch circuit SW5 controlled by the control signal CNT3 is disposed between the nodes VBE1 and VBE2 and the transistors Q1 and Q2. The switch circuit SW5 is an example of a fifth switch circuit.

During the low level period of the control signal CNT3, the switch circuit SW5 connects the node VBE1 to the transistor Q1 and connects the node VBE2 to the transistor Q2. During the high level period of the control signal CNT3, the switch circuit SW5 connects the node VBE1 to the transistor Q2 and connects the node VBE2 to the transistor Q1.

The operation timing of the measurement circuit 108 shown in FIG. 10 is similar to the operation timing of the measurement circuit 106 shown in FIG. 9. However, during the “forward” period of the control signal CNT3, the node VBE1 is connected to the transistor Q1 and the node VBE2 is connected to the transistor Q2. During the “reverse” period of the control signal CNT3, the node VBE1 is connected to the transistor Q2 and the node VBE2 is connected to the transistor Q1.

Thus, in the temperature measurement mode, the difference in electrical characteristics caused by the manufacturing variations of the transistors Q1 and Q2 can be canceled, and the input conversion offset of the operational amplifier AMP caused by the difference in the electrical characteristics of the transistors Q1 and Q2 can be canceled. Since the measurement circuit 108 shown in FIG. 10 can cancel most of all major errors in temperature measurement, it is possible to further realize accuracy in temperature measurement and voltage measurement relative to the measurement circuit 106 shown in FIG. 8.

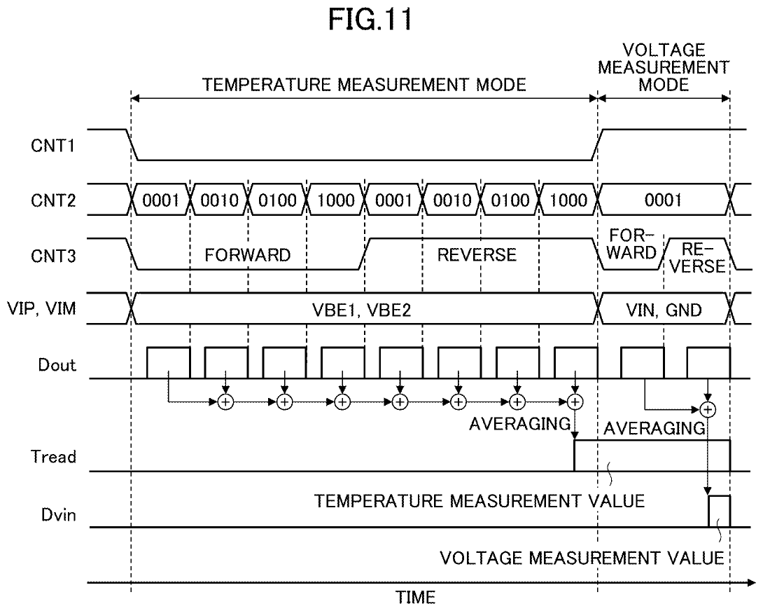

FIG. 11 shows an example of operation timing different from that of FIG. 9 in the measurement circuit 108 of FIG. 10. The same or similar operation as that of FIG. 9 will not be described in detail. FIG. 11 is the same as the operation timing of FIG. 9 except that the control signal CNT3 changes to a low level and a high level in the voltage measurement mode.

The ADC outputs a digital output value Dout to the arithmetic circuit OPC during a “forward” period and a “reverse” period of the control signal CNT3 in the voltage measurement mode. The arithmetic circuit OPC integrates the digital output value Dout received twice from the ADC during the voltage measurement mode, calculates an average value of the two integrated digital output values Dout, and outputs the calculated average value as the voltage measurement value Dvin. This makes it possible to cancel the offset of the operational amplifier AMP that occurs not only when the temperature is measured but also during measurement of the input voltage VIN.

As described above, in the fifth embodiment, the same effects as those in the first to fourth embodiments can be obtained. Further, in Embodiment 5, the offset of the operational amplifier AMP that occurs not only when the temperature is measured but also when the input voltage VIN is measured can be canceled. As a result, the deterioration of the accuracy of the voltage measurement value Dvin that is measured by using the common measurement circuit 108 can be further suppressed. Note that the switch circuit SW5 may be disposed between the transistors M1 and M2 and the transistors Q1 and Q2 in FIGS. 3 and 5.

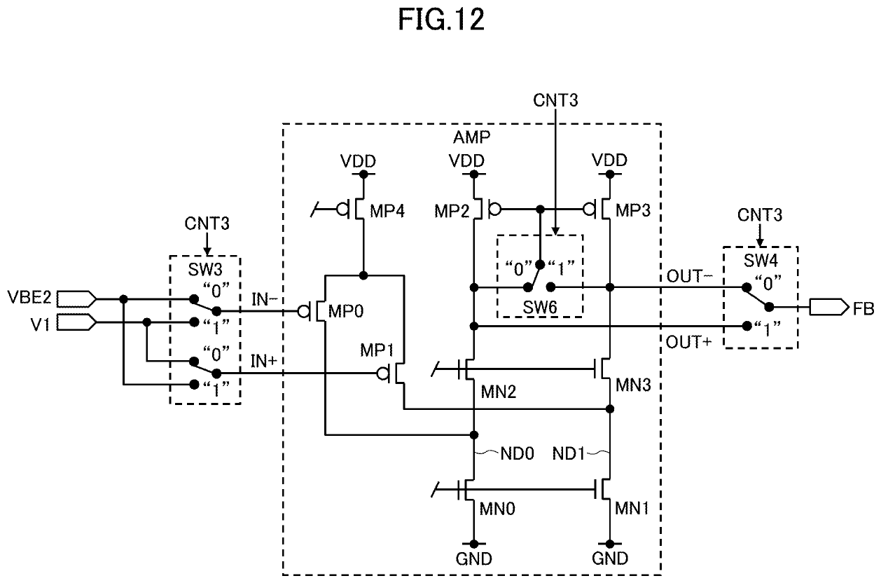

FIG. 12 shows an example of the operational amplifier AMP and the switch circuits SW3 and SW4 in FIGS. 8 and 10. In the switch circuit SW3, when the control signal CNT3 is at a low level (“0”), the node VBE1 is connected to the input IN− of the operational amplifier AMP, and the node V1 is connected to the input IN+ of the operational amplifier AMP. In the switch circuit SW3, when the control signal CNT3 is at a high level (“1”), the node VBE1 is connected to the input IN+ of the operational amplifier AMP, and the node V1 is connected to the input IN− of the operational amplifier AMP.

In the switch circuit SW4, when the control signal CNT3 is at a low level (“0”), the output OUT− of the operational amplifier AMP is connected to the feedback node FB. In the switch circuit SW4, when the control signal CNT3 is at a high level (“1”), the output OUT+of the operational amplifier AMP is connected to the feedback node FB.

The operational amplifier AMP includes P-channel MOS transistors MP0, MP1, MP2, MP3, and MP4, N-channel MOS transistors MN0, MN1, MN2, and MN3, and a switch circuit SW6. The switch circuit SW6 is an example of a sixth switch circuit. In the following, the P-channel MOS transistors MP0, MP1, MP2, MP3, and MP4 are also referred to simply as transistors MP0, MP1, MP2, MP3, and MP4. The N-channel MOS transistors MN0, MN1, MN2, and MN3 are also referred to simply as transistors MN0, MN1, MN2, and MN3.

The transistors MP2, MN2, and MN0 are connected in series between the power supply line VDD and the ground line GND. The transistors MP3, MN3, and MN1 are connected in series between the power supply line VDD and the ground line GND. Gates of the transistors MP2 and MP3 are connected to an output OUT+, which corresponds to drains of the transistors MP2 and MN2, or an output OUT−, which corresponds to drains of the transistors MP3 and MN3, via a switch circuit SW6.

The switch circuit SW6 connects the gates of transistors MP2 and MP3 to outputs OUT+ when a control signal CNT3 is at low level (“0”), and connects the gates of transistors MP2 and MP3 to outputs OUT− when the control signal CNT3 is at high level (“1”). The gates of transistors MN2 and MN3 are each set to a predetermined voltage that causes conduction between the source and the gate of each of the transistors MN2 and MN3. The gates of transistors MN0 and MN1 are each set to a predetermined voltage that causes conduction between the source and the gate of each of the transistors MN0 and MN1.

The transistor MP4 has a source connected to power supply line VDD, a gate set to a predetermined voltage that causes conduction between the source and the gate of the transistor MP4, and a drain connected to the sources of transistors MP0 and MP1. The transistor MP0 has a gate connected to input IN− and a drain connected to a node ND0 that is the source of the transistor MN2 and the drain of the transistor MN0. The transistor MP1 has a gate connected to an input IN+ and a drain connected to a node ND1 that corresponds to the source of transistor MN3 and the drain of the transistor MN1. Transistors MP0 and MP1 operate as a one-stage amplifier in which a common source pair is folded.

Since transistors M33 to M30 shown in FIG. 10 and the like operate as a source ground amplifier (single-stage amplifier), the operational amplifier AMP shown in FIG. 12 is preferably a single-stage amplifier composed of transistors MP0 and MP1 from the viewpoint of negative feedback stability.

An offset voltage of the operational amplifier AMP shown in FIG. 12 is mainly caused by mismatch between three combinations of transistors MP0 and MP1, transistors MP2 and MP3, and transistors MN0 and MN1. When gate-to-source potentials of the transistors MP0 and MP1 are the same, ideally the drain currents of the transistors MP0 and MP1 are the same, but current differences occur due to manufacturing variations of the transistors MP0 and MP1. Mismatch between a pair of transistors MP2 and MP3 and a pair of transistors MN0 and MN1 also causes the offset voltage.

Therefore, in the operational amplifier AMP shown in FIG. 12, measurements are performed using two settings: one when the control signal CNT3 is set to low level (“0”) and the other when the control signal CNT3 is set to high level (“1”). The offset voltages of the operational amplifier AMP when the control signal CNT3 is set to low level (“0”) and when the control signal CNT3 is set to high level (“1”) have the same magnitude but opposite polarity. Therefore, the influence of the offset can be canceled by taking the average of the two measurements.

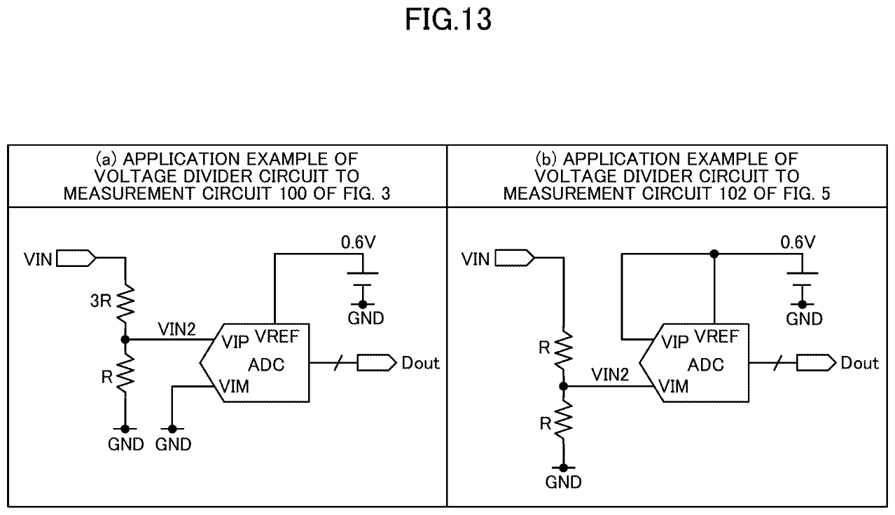

FIG. 13 shows an example of the main part of the measurement circuit according to a sixth embodiment. In FIGS. 3, 5, 6, 8, and 10, the input voltage VIN is directly supplied to the input node of the ADC. Since the ADC used in the above-described embodiments is used to measure a DC voltage, a ΔΣ-type architecture is suitable. When a ΔΣ-type ADC is used, for example, there is a restriction that the input voltage (VIP-VIM) is limited to a range from −0.8×VREF to +0.8×VREF.

When this restriction is examined in the measurement circuit 100 of FIG. 3 and the measurement circuit 102 of FIG. 5, when the temperature T is 300 K and the VBE is 0.6 V, the measurable range of the input voltage VIN by the ACD is 0 V to 0.48 V (=0.6 V×0.8) in the measurement circuit 100. In the measurement circuit 102, the VIN is 0.12 V (=0.6 V−0.6 V×0.8) to 1.08 V (=0.6 V+0.6 V×0.8). These measurable ranges may not be sufficient depending on the application of the measurement circuit.

Therefore, the measurable voltage range can be widened by supplying a divided voltage generated by dividing the input voltage VIN by a voltage dividing circuit to the ADC. In the application example of the voltage dividing circuit to the measurement circuit 100 of FIG. 3 shown in FIG. 13 (a), resistors 3R and R having a resistance ratio of 3:1 are connected in series between the input voltage line VIN and the ground line GND via a node VIN2, and the node VIN2 is connected to the positive input terminal VIP of the ADC. Thus, the applied voltage VIN2 to the ADC can be scaled to ¼. For example, in the measurement circuit 100 of FIG. 3, an allowable input voltage range of the input voltage VIN is from 0 V to 0.48 V, but in FIG. 13 (a), the allowable input voltage range of the input voltage VIN can be from 0 V to 1.92 V.

In an application example of the voltage dividing circuit to the measurement circuit 102 of FIG. 5 shown in FIG. 13(b), resistors R and R having a resistance ratio of 1:1 are connected in series between the input voltage line VIN and the ground line GND via the node VIN2, and the node VIN2 is connected to the negative-side input terminal VIM of the ADC. For example, by applying the voltage dividing circuit of FIG. 13(b) to the measurement circuit 102 of FIG. 5, a lower limit of the allowable input voltage range can be set to 0.24 V (=(0.6−0.6 V×0.8)×2), and an upper limit of the allowable input voltage range can be set to 2.16 V (=(0.6 V+0.6 V×0.8)×2).

Note that the method for scaling the input voltage range of the input voltage VIN is not limited to the voltage dividing circuit by resistors shown in FIG. 13. For example, if the ADC is a switched capacitor ΔΣ type, the input sensitivity can be changed by switching the ratio between the sampling capacitance and the reference capacitance.

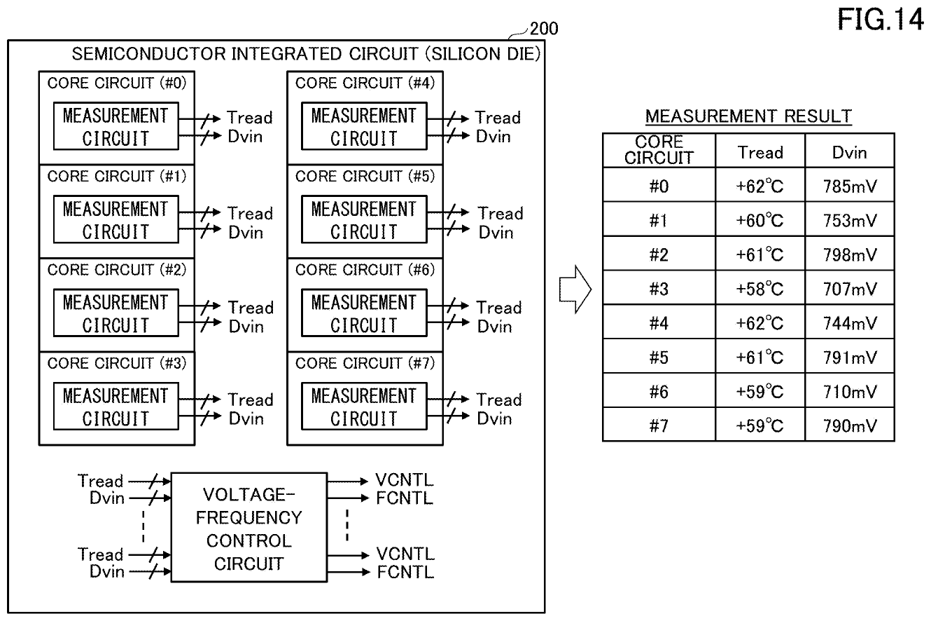

FIG. 14 shows an example of a semiconductor integrated circuit in which any of the measurement circuits of the above-described embodiments is mounted. For example, the semiconductor integrated circuit 200 shown in FIG. 14 is a multi-core processor formed on a silicon die and including a plurality of core circuits, each of which includes one of the measurement circuits of the above-described embodiments. For example, each of the core circuits is a CPU core that executes a calculation process by executing an instruction. Although FIG. 14 shows an example in which the semiconductor integrated circuit 200 has eight core circuits (#0 to #7), the number of core circuits is not limited to eight as long as there are a plurality of core circuits.

The measurement circuit in each of the core circuits outputs a temperature measurement value Tread and a voltage measurement value Dvin. FIG. 14 shows examples of the temperature measurement value Tread and the voltage measurement value Dvin measured by the measurement circuit of each of the core circuits as measurement results. The temperature measurement value Tread and the voltage measurement value Dvin output from the measurement circuit of each of the core circuits are supplied to, for example, a voltage frequency control circuit mounted on the semiconductor integrated circuit 200.

For example, on the basis of the temperature measurement value Tread received from each of the core circuits, the voltage frequency control circuit outputs a voltage control signal VCNT to a voltage generation circuit (not shown) that generates a power supply voltage to be supplied to each of the core circuits. Further, on the basis of a voltage measurement value Dvin received from each of the core circuits, the voltage frequency control circuit outputs a frequency control signal FCNT to a PLL (Phase Locked Loop) circuit (not shown) that adjusts the frequency of a clock to be supplied to each of the core circuits. The voltage frequency control circuit controls the frequency of the clock and the power supply voltage to be supplied to the plurality of core circuits in a changeable manner.

For example, the voltage generation circuit and the PLL circuit are mounted on the semiconductor integrated circuit 200. For example, the voltage frequency control circuit may implement DVFS for dynamically controlling the power supply voltage and the frequency of the clock for each core circuit. The voltage frequency control circuit may control either the frequency of the clock or the power supply voltage.

Although the present disclosure has been described based on the embodiments, the present disclosure is not limited to the requirements shown in the above embodiments. These configurations may be changed without departing from the scope of the present disclosure and may be appropriately determined according to the application.

What is claimed is:

1. A measurement circuit comprising:
a first field effect transistor and a first bipolar transistor that are coupled between a first power supply line and a second power supply line via a first node;
a second field effect transistor and a second bipolar transistor that are coupled between the first power supply line and the second power supply line via a second node;
an analog-to-digital conversion circuit configured to:
convert an analog voltage indicating a difference between a voltage at a first differential input node and a voltage at a second differential input node into a digital output value, by using a voltage at the first node as a reference voltage, and
output the digital output value; and
a first switch circuit provided between:
an input side node including a voltage measurement node to which a voltage to be measured is supplied, the first node, and the second node, and
an output side node including the first differential input node and the second differential input node, the first switch circuit being configured to switch a connection between the input side node and the output side node in accordance with a plurality of measurement modes for measuring a plurality of types of physical quantities, the plurality of measurement modes including a first measurement mode and a second measurement mode.

2. The measurement circuit according to claim 1, wherein the first switch circuit is configured to:
couple the first node to the first differential input node and couple the second node to the second differential input node, in the first measurement mode, and
couple the voltage measurement node to the first differential input node and couple a fixed voltage node, to which a fixed voltage is supplied, to the second differential input node, in the second measurement mode.

3. The measurement circuit according to claim 1, wherein the first switch circuit is configured to:
couple the second node to the second differential input node in the first measurement mode, and
couple the voltage measurement node to the second differential input node in the second measurement mode,
wherein the first differential input node is coupled to the first node regardless of the plurality of measurement modes.

4. The measurement circuit according to claim 1, further comprising:
an arithmetic circuit configured to perform different arithmetic operations in respective ones of the measurement modes by using the digital output value output from the analog-to-digital conversion circuit, and output a value indicating a physical quantity of a type corresponding to a target measurement mode among the plurality of measurement modes.

5. The measurement circuit according to claim 2, wherein the first measurement mode is a temperature measurement mode for measuring a temperature based on the digital output value that is output from the analog-to-digital conversion circuit, and
wherein the second measurement mode is a voltage measurement mode for measuring a voltage based on the digital output value that is output from the analog-to-digital conversion circuit.

6. The measurement circuit according to claim 5, further comprising:
a second switch circuit coupled between a first group of the first field effect transistor and the second field effect transistor and a second group of the first bipolar transistor and the second bipolar transistor,
wherein the first group of the first field effect transistor and the second field effect transistor include three or more third field effect transistors, and
wherein, in the temperature measurement mode, the second switch circuit is configured to switch a combination of the third field effect transistors to be coupled to the second group of the first bipolar transistor and the second bipolar transistor.

7. The measurement circuit of claim 5, further comprising:
a comparison circuit configured to:
receive the voltage at the first node and the voltage at the second node at a third differential input node and a fourth differential input node,
compare the voltage at the first node with the voltage at the second node, and
output a voltage indicating a comparison result to a first differential output node and a second differential output node;
a third switch circuit coupled between a first group of the first node and the second node and a second group of the third differential input node and the fourth differential input node, the third switch circuit being configured to switch connections between the first group of the first node and the second node and the second group of the third differential input node and the fourth differential input node; and
a fourth switch circuit configured to couple one of the first differential output node and the second differential output node to a feedback node coupled to a gate of the first field effect transistor and a gate of the second field effect transistor,
wherein, in the temperature measurement mode and the voltage measurement mode, the third switch circuit and the fourth switch circuit are configured to switch the connections.

8. The measurement circuit of claim 5, further comprising:
a fifth switch circuit coupled between a first group of the first field effect transistor and the second field effect transistor and a second group of the first bipolar transistor and the second bipolar transistor, the fifth switch circuit being configured to switch connections between the first group of the first field effect transistor and the second field effect transistor and the second group of the first bipolar transistor and the second bipolar transistor,
wherein, in the temperature measurement mode and the voltage measurement mode, the fifth switch circuit is configured to switch the connections.

9. The measurement circuit according to claim 6, further comprising:
an arithmetic circuit configured to:
perform different operations in respective ones of the measurement modes by using the digital output value that is output from the analog-to-digital conversion circuit, and
output a value indicating a physical quantity of a type corresponding to a target measurement mode among the plurality of measurement modes,
wherein the arithmetic circuit is configured to calculate an average value of the digital output values each of which is output from the analog-to-digital conversion circuit for each switching of connections, and to output a calculation result as a temperature measurement value or a voltage measurement value.

10. The measurement circuit according to claim 7, further comprising:
an arithmetic circuit configured to:
perform different operations in respective ones of the measurement modes by using the digital output value that is output from the analog-to-digital conversion circuit, and
output a value indicating a physical quantity of a type corresponding to a target measurement mode among the plurality of measurement modes,
wherein the arithmetic circuit is configured to calculate an average value of the digital output values each of whitch is output from the analog-to-digital conversion circuit for each switching of the connections, and to output a calculation result as a temperature measurement value or a voltage measurement value.

11. The measurement circuit according to claim 8, further comprising:
an arithmetic circuit configured to:
perform different operations for respective ones of the measurement modes by using the digital output value that is output from the analog-to-digital conversion circuit, and
output a value indicating a physical quantity of a type corresponding to a target measurement mode among the plurality of measurement modes,
wherein the arithmetic circuit is configured to calculate an average value of the digital output values each of which is output from the analog-to-digital conversion circuit for each switching of the connections, and to output a calculation result as a temperature measurement value or a voltage measurement value.

12. The measurement circuit according to claim 1, further comprising:
a comparison circuit configured to compare the voltage at the first node with the voltage at the second node, and output a voltage indicating a comparison result to a gate of the first field effect transistor and a gate of the second field effect transistor.

13. The measurement circuit according to claim 12, further comprising:
a resistor coupled between the second field effect transistor and the second node,
wherein the comparison circuit is configured to compare the voltage at the first node with a voltage generated at a third node between the second field effect transistor and the resistor.

14. The measurement circuit according to claim 1, further comprising:
a switch control circuit configured to control the first switch circuit according to a target measurement mode to switch a connection between the input side node and the output side node.

15. A semiconductor integrated circuit comprising:
the measurement circuit of claim 1; and
a core circuit configured to perform calculation processing according to a physical quantity of type corresponding to a target measuring mode, the physical quantity being measured by the measurement circuit.

16. The semiconductor integrated circuit according to claim 15, wherein the first switch circuit is configured to:
couple the first node to the first differential input node and couple the second node to the second differential input node, in the first measurement mode, and
couple the voltage measurement node to the first differential input node and couple a fixed voltage node, to which a fixed voltage is supplied, to the second differential input node, in the second measurement mode.

17. The semiconductor integrated circuit according to claim 15, wherein the first switch circuit is configured to:
couple the second node to the second differential input node in the first measurement mode, and
couple the voltage measurement node to the second differential input node in the second measurement mode,
wherein the first differential input node is coupled to the first node regardless of the plurality of measurement modes.

18. The semiconductor integrated circuit of claim 15, further comprising:
an arithmetic circuit configured to perform different arithmetic operations in respective ones of the measurement modes by using the digital output value output from the analog-to-digital conversion circuit, and output a value indicating a physical quantity of type corresponding to a target measurement mode among the plurality of measurement modes.

19. The semiconductor integrated circuit according to claim 15, further comprising:
a voltage frequency control circuit configured to variably control a frequency of a clock supplied to the core circuit and a power supply voltage,
wherein the voltage frequency control circuit is configured to adjust one or both of the frequency of the clock and the power supply voltage based on a physical quantity of a type corresponding to a target measurement, the physical quantity being measured by the measurement circuit.

20. The semiconductor integrated circuit according to claim 15, further comprising:
a voltage frequency control circuit configured to variably control a frequency of a clock and a power supply voltage supplied to each of a plurality of core circuits, each of the plurality of core circuits being the core circuit,
wherein the voltage frequency control circuit is configured to adjust one or both of the frequency of the clock and the power supply voltage, based on a physical quantity of a type corresponding to a target measurement mode, the physical quantity being measured by a plurality of measurement circuits, and each of the plurality of measurement circuits being the measurement circuit.
